(19) United States
(12) Patent Application Publication
(10) Pub. No.: US 2017/0316963 A1
(43) Pub. Date: Nov. 2, 2017

(54) DIRECT OPTICAL HEATING OF SUBSTRATES

(71) Applicant: Applied Materials, Inc., Santa Clara, CA (US)

(72) Inventor: Vijay D. Parkhe, San Jose, CA (US)

(21) Appl. No.: 15/490,822

(22) Filed: Apr. 18, 2017

Related U.S. Application Data
(60) Provisional application No. 62/328,990, filed on Apr. 28, 2016.

(51) Int. Cl. H01L 21/67; H01L 21/263

(52) U.S. Cl. CPC H01L 21/67115; H01L 21/2636

(57) ABSTRACT

A substrate support assembly includes a ceramic plate having an optical transmittance of at least 60% at a predetermined wavelength, the ceramic plate comprising a top surface and a bottom surface, wherein the top surface is to support a substrate. The substrate support assembly further includes a cooling base coupled to the bottom surface of the ceramic plate. The substrate support assembly further includes a light carrying medium disposed in the base, the light carrying medium to direct light having the predetermined wavelength onto the bottom surface of the ceramic plate, wherein a majority of energy from the light is to pass through the ceramic plate or light carrying medium attached inside holes of ceramic plate and be absorbed by the substrate.

### RELATED APPLICATIONS

This patent application claims the benefit under 35 U.S.C. §119(e) of U.S. Provisional Application No. 62/328,990, filed Apr. 28, 2016, which is herein incorporated by reference.

### TECHNICAL FIELD

Embodiments of the present invention relate to an apparatus for controlling substrate temperature using optical heating.

### BACKGROUND

Conventional electronic device manufacturing systems may include one or more process chambers. In some electronic device manufacturing systems, the one or more process chambers may be arranged around a mainframe housing having a transfer chamber and one or more load lock chambers. These systems may employ one or more process chambers that may perform a process on a substrate (e.g., a wafer) inserted into the process chamber. During processing, wafers may rest on a pedestal (e.g., a substrate support) and the temperature thereof may be controlled (e.g., heated or cooled) at one or more times during the process. Conventionally, heating may be provided by resistive heaters provided within the pedestal in some embodiments.

### SUMMARY

In one aspect, a substrate support assembly includes a ceramic plate having an optical transmittance of at least 60% at a predetermined wavelength, the ceramic plate comprising a top surface and a bottom surface, wherein the top surface is to support a substrate. The substrate support assembly further includes a base coupled to the bottom surface of the ceramic plate. The substrate support assembly further includes a light carrying medium disposed in the base, the light carrying medium to direct light having the predetermined wavelength onto the bottom surface of the ceramic plate, wherein a majority of energy from the light is to pass through the ceramic plate and be absorbed by the substrate.

In another aspect, a substrate support assembly includes a ceramic plate comprising a top surface and a bottom surface, wherein the top surface is to support a substrate. The substrate support assembly additionally includes a base coupled to the bottom surface of the ceramic plate, a light source disposed in the base, and a light carrying medium disposed in the base. The light carrying medium is to direct light from the light source onto the bottom surface of the ceramic plate.

In another aspect, a substrate support assembly includes a ceramic plate comprising a top surface and a bottom surface, wherein the top surface is to support a substrate. The substrate support assembly additionally includes a cooling base coupled to the bottom surface of the ceramic plate, wherein the cooling base is to be maintained at or below a first target temperature and is to cool the substrate to the first target temperature. The substrate support assembly additionally includes a light carrying medium disposed in the cooling base, the light carrying medium to direct light from a light source onto at least one of the substrate or the bottom surface of the ceramic plate, wherein the light is to heat the substrate to a second target temperature that is above the first target temperature.

In another aspect, a method comprises performing, by a substrate support assembly, optical heating of a substrate to a first target temperature at a first rate of approximately 2-20° C. per second. The method further includes activating an electrode of the substrate support assembly to thermally couple the substrate to the substrate support assembly, wherein the substrate support assembly is maintained at a second temperature that is below the target temperature. The method further includes cooling the substrate to a second target temperature that is below the first target temperature at a second rate of approximately 2-20° C. per second. The method may additionally include alternately heating and cooling the substrate to the first target temperature and the second target temperature.

Numerous other aspects are provided in accordance with these and other embodiments of the invention. Other features and aspects of embodiments of the present invention will become more fully apparent from the following description, the appended claims, and the accompanying drawings.

### BRIEF DESCRIPTION OF THE DRAWINGS

Embodiments of the present invention are illustrated by way of example, and not by way of limitation, in the figures of the accompanying drawings in which like references indicate similar elements.

FIG. 1 illustrates a schematic top view of an electronic device processing system including optical fiber heating in one or more process chambers according to embodiments.

FIG. 2 illustrates a schematic partially cross-sectioned view of a substrate temperature control system including optical fiber heating, wherein the optical fibers are laid in channels according to embodiments.

FIG. 3 illustrates a schematic top view of a portion of a substrate support assembly with the upper member removed to show positioning of the optical fibers according to embodiments.

FIG. 4 illustrates a cross-sectional side view of a portion of a substrate support assembly with light-based heating capability, in accordance with embodiments of the present invention.

FIG. 5 illustrates a cross-sectional side view of a portion of a substrate support assembly with light-based heating capability, in accordance with embodiments of the present invention.

FIG. 6 illustrates a cross-sectional side view of a portion of a substrate support assembly with light-based heating capability, in accordance with embodiments of the present invention.

FIG. 7 illustrates a cross-sectional side view of a portion of a substrate support assembly with light-based heating capability, in accordance with embodiments of the present invention.

FIG. 8 illustrates a cross-sectional side view of a portion of a substrate support assembly with light-based heating capability, in accordance with embodiments of the present invention.

FIG. 9 illustrates a flowchart depicting a method of rapidly heating and cooling a substrate during a manufacturing process, in accordance with embodiments of the present invention.

FIG. 10 is a chart illustrating transmittance of AlON, sapphire and spinal at wavelengths of 0.5-7 microns.

FIG. 11 is a chart illustrating transmittance of silicon as a function of wavelength in nanometers.

### DETAILED DESCRIPTION OF EMBODIMENTS

Embodiments of the present invention provide a substrate support assembly that includes optical fibers or other light transmission media that are used to directly heat substrates supported by the substrate support assembly. The substrate support assembly may include a ceramic plate coupled to a base. The ceramic plate has a top surface that is to support a substrate and a bottom surface that may be bonded to the base. The base includes multiple channels and light transmission media such as light pipes or optical fibers disposed in the channels. In one embodiment, the ceramic plate is substantially transparent to a range of light wavelengths emitted by the light transmission media. In one embodiment, the ceramic plate includes through channels, and the transmission media are inserted into the through fibers to direct light directly on the substrate. Additionally, the substrate is substantially opaque at the range of light wavelengths emitted by the light transmission media.

Due to the fact that the ceramic plate is substantially transparent to the light emitted by the light carrying media or has through channels, little or no energy from the light may be absorbed by the ceramic plate. The light may pass through the ceramic plate and then be absorbed by the substrate. Accordingly, the substrate may be heated up by the light emitted by the light carrying media without the ceramic plate heating up either because ceramic plate is partially transparent and cooling plate is attached to the ceramic plate or the ceramic plate has holes to pass light carrying medium to the top surface behind wafer. Heating up the substrate directly may be much more efficient in terms of energy usage than heating up the ceramic plate. Additionally, by heating up the substrate directly without substantially affecting a temperature of the ceramic plate, the ceramic plate may be maintained at a target temperature that is different than a target temperature of the substrate.

The ability to heat up the substrate directly without heating up the ceramic plate of the substrate support assembly and the ability to cool the substrate introduces the possibility for new processes that implement heating and cooling on same substrate support assembly that were previously unpractical. For example, in embodiments the substrate can be heated to higher temperatures than is recommended for the ceramic plate. Additionally, the substrate can be heated and cooled at a much higher rate than was previously achievable using systems that heated portions of the substrate support and indirectly heated the substrate based on contact between the substrate an the heated substrate support. Heating of the substrate can be performed in embodiments at rates of up to 20° C. per second (° C./s) in embodiments. Cooling of the substrate can also be performed in embodiments at similar rates by maintaining the ceramic plate of the substrate support assembly at a lower temperature than the substrate is heated to. The substrate can be rapidly cooled in such situations by thermally coupling the heated substrate to the cooler ceramic plate of the substrate support assembly. The thermal coupling can be achieved by activating an electrode (e.g., a chucking electrode) and pumping a gas such as helium or argon into a region between the substrate and the ceramic plate.

Embodiments are described herein with reference to optical fibers that are used as a medium that delivers light to target areas. However, it should be understood that any type of light transmission media may be used to deliver the light to the target areas. The light transmission media may include light pipes that include, but are not limited to, optical fibers. Other types of light transmission media that may be used include, for example, optical waveguides. Accordingly, it should be understood that embodiments described herein with reference to optical fibers also apply to any other type of light transmission media.

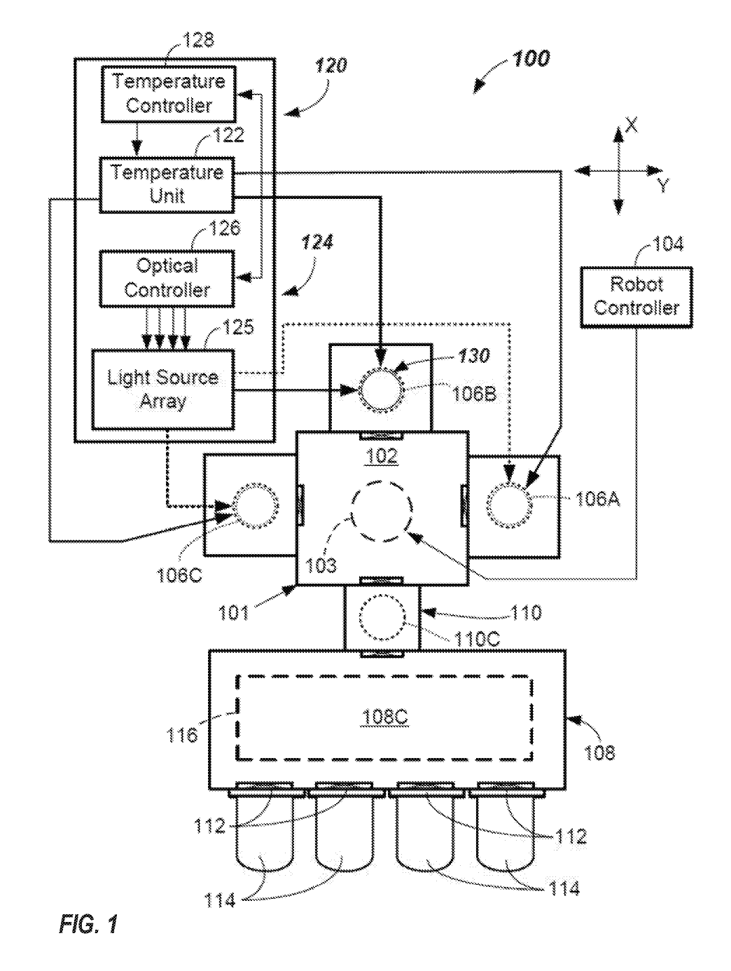

FIG. 1 illustrates a schematic top view diagram of an example embodiment of an electronic device processing system 100 including optical fiber heating according to one or more embodiments of the present invention. The electronic device processing system 100 may include a housing 101 having walls defining a transfer chamber 102. Walls may include side walls, floor, and ceiling, for example. A robot 103 (shown as a dotted circle) may be at least partially housed within the transfer chamber 102. The robot 103 may be configured and adapted to place or extract substrates to and from various destinations via operation of moveable arms of the robot 103. “Substrates” as used herein shall mean articles used to make electronic devices or electrical circuit components, such as silicon-containing wafers or articles, patterned or masked silicon wafers or articles, or the like. However, the apparatus, systems, and methods described herein may have broad utility wherever temperature control of a substrate is useful. Embodiments of the invention may be useful for controlled high-temperature heating, such as above 200° C., above 500° C., about 650° C., or even higher temperatures. Embodiments of the present invention may also be useful for lower temperature heating, such as at temperatures of 120-200° C.

Robot 103, in the depicted embodiment, may be any suitable type of robot adapted to service the various chambers that are coupled to, and accessible from, the transfer chamber 102. Robot 103 may be a selective compliance assembly robot arm (SCARA) robot or other suitable robot type.

The motion of the various arms of the robot 103 may be controlled by suitable commands to a drive assembly (not shown) containing a plurality of drive motors from a robot controller 104. Signals from the robot controller 104 may cause motion of the various components of the robot 103 to cause movement of substrates between the process chambers 106A-106C and one or more load lock chambers 110C. Suitable feedback mechanisms may be provided for one or more of the components by various sensors, such as position encoders, or the like. The robot 103 may include a base that is adapted to be attached to a wall (e.g., a floor or ceiling) of the housing 101. Arms of the robot 103 may be adapted to be moveable in an X-Y plane (as shown) relative to the housing 101. Any suitable number of arm components and end effectors (sometimes referred to as “blades”) adapted to carry the substrates may be used.

Additionally, the drive assembly of the robot 103 may include Z-axis motion capability in some embodiments. In particular, vertical motion of the arms along the vertical direction (into and out of the paper in FIG. 1) may be provided so as to place and pick substrates to and from the process chambers 106A-106C and the one or more load lock chambers 110C.

In the depicted embodiment, transfer chamber 102 may have one or more process chambers 106A-106C coupled to and accessible therefrom, at least some of which are adapted to carry out high-temperature processing on the substrates inserted therein. The process chambers 106A-106C may be coupled to facets of the housing 101, and each process chamber 106A-106C may be configured and operable to carry out a suitable process (e.g. a PECVD process or etch process) on the substrates. It should be understood that the substrate support assembly 130 including optical fiber heating described herein may have utility for other processes taking place at elevated temperature, such as physical vapor deposition, etch and ion implant, or the like. In particular, one or more of the processes taking place in the process chambers 106A-106C may include temperature control via direct optical heating of a substrate in accordance with an aspect of the invention.

Within the electronic device processing system 100, substrates may be received from a factory interface 108, and also exit the transfer chamber 102 into the factory interface 108 through load lock chamber 110C of a load lock apparatus 110. The factory interface 108 may be any enclosure having wall surfaces forming the factory interface chamber 108C. One or more load ports 112 may be provided on some surfaces of the factory interface 108 and may be configured and adapted to receive (e.g., dock) one or more substrate carriers 114 (e.g., front opening unified pods—FOUPs) such as at a front surface thereof.

Factory interface 108 may include a suitable load/unload robot 116 (shown dotted) of conventional construction within a factory interface chamber 108C. The load/unload robot 116 may be configured and operational to extract substrates from the interior of the one or more substrate carriers 114 and feed the substrates into the one or more load lock chambers 110C of load lock apparatus 110.

In accordance with one or more embodiments of the invention, a substrate support assembly 130 that includes a substrate support (e.g., an electrostatic chuck) may be provided in one or more of the process chambers 106A-106C. The substrate support may be a ceramic plate 234, which may be coupled to a base 244. The base may be a ceramic base, a metal base, or another type of base. The base 244 may include channels into which optical fibers 235 are inserted. As will be apparent from the following, a substrate support assembly 130 adapted to provide light-based heating of a substrate is provided. The description herein will focus on providing the substrate support assembly 130 in process chamber 106B. However, an identical or similar substrate support assembly 130 may be included in one or both of the other process chambers 106A, 106C. In some embodiments, the substrate support assembly 130 may be included in all process chambers 106A-106C. More or less numbers of process chambers including the substrate support assembly 130 may be provided.

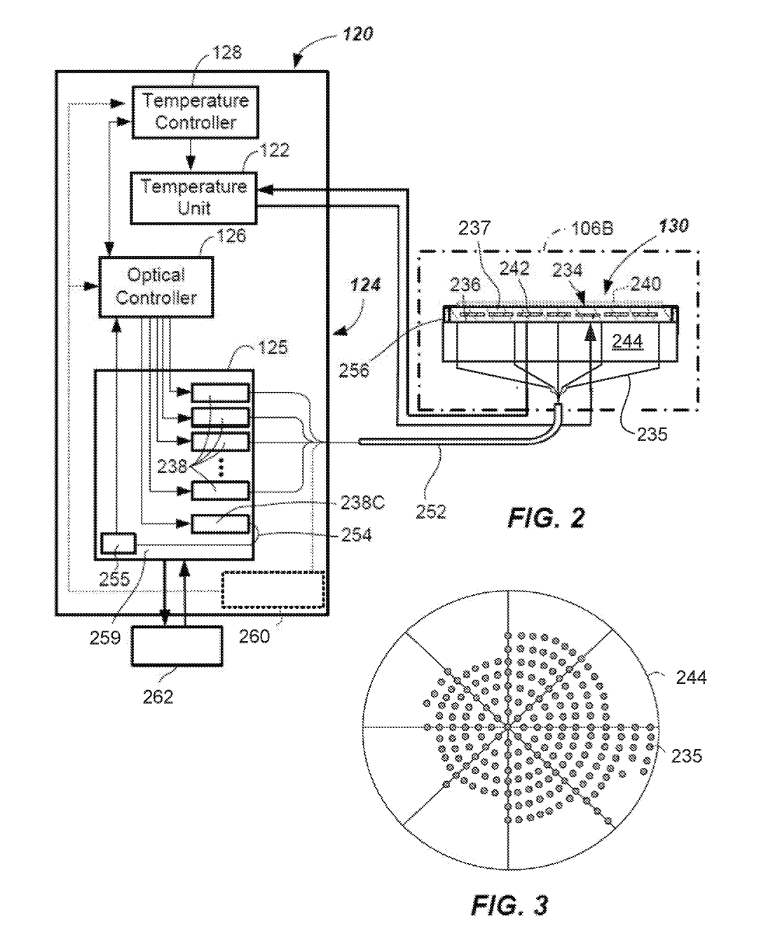

FIG. 2 illustrates a schematic partially cross-sectioned view of a substrate temperature control system 120 including optical fiber heating, wherein the optical fibers are laid in channels according to embodiments. Referring now to FIGS. 1 and 2, in some embodiments, a temperature unit 122 that may be coupled to one or more resistive heating elements 242 may be used in conjunction with optical fiber heating provided by the substrate support assembly 130 to control a temperature of one or more portions of a substrate 240 to a target temperature. The resistive heating elements 242 may provide a first level of temperature control of a substrate support (e.g., of a ceramic plate or electrostatic chuck) and/or supported substrate 240 and the optical fibers 235 may provide a second level of temperature control of the substrate 240. The optical fibers 235 may emit light at a wavelength that substantially passes through the ceramic plate 234 and directly heats the substrate 240.

The optical fibers 235 may be made of sapphire, plastic, glass, and/or other materials. Optical fibers 235 may include any suitable optical fiber type, such as graded-index optical fiber, step-index single mode optical fiber, multi-mode optical fiber, or even photonic crystal optical fiber. Optical fibers 235 that exhibit relatively high bend resistance may be used in some embodiments. Relatively high numerical aperture (NA) fibers may be used, such as NA of greater than about 0.1, greater than about 0.2, or even greater than about 0.3. Any suitable number of optical fibers 235 may be used, such as 20 or more, 50 or more, 100 or more, 200 or more 300 or more, 400 or more, and even up to 500 or more. Some of the optical fibers 235 may be fiber thermocouples. The optical fibers 235 may have coatings to improve performance in some embodiments.

In alternative embodiments, the substrate support assembly 130 may not include resistive heating elements 242. Instead, optical fibers 235 may provide a single level of temperature control of the substrate 240. The optical fibers 235 may emit light at a wavelength that substantially passes through the substrate support and directly heats the substrate 240.

At a system level, the temperature control may be provided, in the depicted embodiment, by a substrate temperature control system 120. Substrate temperature control system 120 may be a subpart of the electronic device processing system 100. Substrate temperature control system 120 may include the temperature unit 122 that may couple and provide power to the resistive heating elements 242 (e.g., metal resistive heating elements or traces) and which may constitute a first source of temperature control (e.g., heating) to one or more of the chambers (e.g., process chambers 106A, 106B, 106C).

An optical heating system 124 may operate as a second heating system in conjunction with the temperature unit 122 and resistive heating elements 242 in some embodiments. Alternatively, substrate temperature control system 120 may not include temperature unit 122, and optical heating system 124 may be used to control the temperature of substrates. For example, the optical heating system 124 may be the sole heating system adapted to heat the substrates 240 within the one or more process chambers 106A-106C.

Optical heating system 124 may include a light source array 125 or a single light source coupled (e.g., optically coupled) to the substrate support assembly 130, and an optical controller 126. The light source array 125 may include multiple light sources 238. Each light source 238 may be a laser diode, such as a single emitter diode, in some embodiments. The laser diode may have any suitable output wavelength range, such as between about 915 nm and about 980 nm, for example. Other output ranges may be used. Output power may be modulated between about 0 W to about 10 W. However, ever higher power diodes (e.g., >10 W) may be used. The laser diode may include an optical fiber output having a 105 or 110 micron core diameter, for example. For example, a model PLD-10 from IPG Photonics® of Oxford, Mass. may be used. Other types of light sources 238 may be alternatively used. According to embodiments, between about 1 and about 500 light sources 238 may be used. As shown, the light sources 238 may be rest upon or be in thermal engagement with a common heat sink 259, which may be cooled (e.g., liquid cooled) to between about 20° C. and about 30° C. by a cooling source 262. Cooling source 262 may be a source of chilled water, for example. Other types of cooling sources 262 may be used.

Each light source 238 may be individually controlled and modulated from a low or zero level of optical power output to a high or maximum level of optical power output. Each light source 238 may be individually controlled in order to control temperature at finite points (pixels) or collectively controlled in groups of optical fibers to control temperatures of one or more regions or zones of the substrate support assembly 130.

Any suitable temperature control philosophy may be implemented. In one control aspect, a highly uniform temperature distribution across an upper surface of the substrate 240 may be sought. In another aspect, a deliberately non-uniform temperature distribution may be beneficial (e.g., hotter or cooler at an edge of the substrate 240). Each temperature profile may be provided, in accordance with aspect of the invention depending on the control philosophy implemented by the optical controller 126. Some embodiments of the invention may provide azimuthal temperature variations.

Substrate temperature control system 120 may include a temperature controller 128 operational to control temperature of the substrate 240 that is being temperature controlled within the chamber (e.g., process chamber 106B). Temperature controller 128 may be operational to control the temperature unit 122 and may interface with the optical controller 126 in some embodiments. The temperature controller 128 may be used to communicate with the optical controller 126 and the temperature unit 122 to control a temperature of the substrate 240 supported by the substrate support assembly 130.

FIG. 3 illustrates a schematic top view of a portion of a substrate support assembly 130 with the upper member (e.g., the ceramic plate) removed to show positioning of the optical fibers 235 according to embodiments. Now referring to FIGS. 2 and 3, the substrate support assembly 130, which is included in optical heating system 124, is described in more detail. Optical heating system 124 may include a substrate support assembly 130, which may include a platform (e.g., an electrostatic chuck that includes a ceramic plate 234 and an embedded chucking electrode) on which a substrate 240 (shown dotted) may rest or be in thermal contact with. Substrate support assembly 130, as shown, includes a ceramic plate 234 with embedded resistive heating elements. In some embodiments, the ceramic plate 234 is an electrostatic chuck. In other embodiments, the ceramic plate 234 is a vacuum chuck. The substrate support assembly additionally includes a base 244 coupled to a bottom surface of the ceramic plate 234. In one embodiment, sidewalls of the ceramic plate 234 and/or base 244 are coated by a plasma resistant coating 256 such as yttria. A top surface of the ceramic plate 234 may also be coated by the plasma resistant coating 256.

The base 244 may be a ceramic base in some embodiments. In other embodiments, the base 244 may be a metal cooling base. The base 244 may be formed of ceramic materials such as AlN or Al₂O₃ in embodiments. The ceramic plate 234 may be AlN, AlON, sapphire, Y₃Al₅O₁₂ (YAG), or spinel in embodiments. The ceramic plate 234 and the base 244 may have been diffusion bonded to form a single ceramic body that includes the base 244 and the ceramic plate 234 in some embodiments. In embodiments the ceramic plate 234 may be bonded to the base 244 by a bond 236. The bond may be a silicone bond, a metal bond (e.g., by brazing), a diffusion bond, or another type of bond.

The base 244 may include multiple channels into which optical fibers (or other light transmission media) 235 are inserted. The optical fibers 235 may be oriented perpendicular to a bottom surface of the ceramic plate 234 as shown. Some or all of the optical fibers 235 may also have other orientations in the base 244, such as at angles of between 45-90 degrees in relation to the bottom surface of the ceramic plate 234.

A top surface 237 of the ceramic plate 234 may have surface features such as mesas, rings, grooves, and so forth. The ceramic plate 234 may include gas channels for delivering backside gas such as helium to a region between the substrate 240 and the top surface 237. The ceramic plate 234 may also include gas channels for pumping air out of the region between the substrate 240 and the top surface 237 to form a vacuum in the region. Use of helium in the region may improve thermal contact between the substrate and the ceramic plate. Use of a vacuum in the region may decrease the thermal contact (and improve thermal separation) between the ceramic plate 234 and the substrate 240.

The plurality of optical fibers 235 are adapted to provide light-based heating of the substrate 240. The plurality of optical fibers 235 may terminate at multiple locations in the base 244. One example layout of the optical fibers 235 in the base 244 is shown in FIG. 3. Optical heating system 124 may include the light source array 125 including a plurality of light sources 238 coupled to at least some, and preferably most or all, of the plurality of optical fibers 235. The optical controller 126 may be configured to control light power (e.g., intensity) channeled into, and carried by, the plurality of optical fibers 235.

In operation, light carried in at least some of the plurality of optical fibers 235 is used to heat the substrate 240 without heating the ceramic plate 234 (or with minimal heating of the ceramic plate 234). When the plurality of optical fibers 235 are positioned and terminated at locations, many local portions of the substrate 240 (or all of the substrate) may be heated. In some embodiments, this heating may be in conjunction with temperature control provided by the temperature unit 122 and the resistive heating elements 242. In other embodiments, the heating by the plurality of optical fibers 235 may be the sole heating provided to the substrate 240.

For example, temperature control may, in some embodiments, cause the substrate 240 (shown dotted) to be heated to a nominal temperature of greater than about 200° C., greater than about 500° C., greater than about 600° C., or even about 650° C., or a greater temperature. For example, temperature control may, in some embodiments, cause the substrate 240 (shown dotted) to be heated to a nominal temperature of between about 600° C. and about 700° C. Such heating may be carried out on substrates 240 within the one or more process chambers 106A-106C in some embodiments. For example, temperature control may, in some embodiments, cause the substrate 240 (shown dotted) to be heated, such as in a PECVD process, an etch process, an atomic layer deposition (ALD) process, and so on.

Some of the optical fibers 235 may include various optical features at the fiber termination, including a diffuse emitter, a lensed tip, or an angled cleave. Such optical features may be used to direct light to one or more surfaces of the diffuser or otherwise minimize light reflection back into the optical fiber 235. Additionally, some optical fibers may be combined at one end to form a larger diameter optical fiber. For example, an optical fiber may have a first diameter at a first end that interfaces with a light source. That optical fiber may split into multiple smaller diameter optical fibers at a second end, where each of the smaller diameter optical fibers is disposed in a separate channel in the base.

One or more holes may be drilled into the base 244 and/or ceramic plate 234 to provide access for electrical lines to connect to the resistive heating elements 242 (also referred to as heating elements) and/or to one or more electrodes. The electrodes may include a chucking electrode that is used to secure a substrate to the substrate support assembly and/or a radio frequency (RF) electrode. The chucking electrode may use electrostatic forces to pull the substrate towards the ceramic plate.

In addition to optical fibers 235 that are used to provide heating, some optical fibers 235 may be used as fiber optic temperature sensors to measure a temperature of the substrate and/or a temperature of the ceramic plate. For example, some optical fibers 235 may be fiber optical thermocouples. Additionally or alternatively, temperature of the substrate and/or temperature of the ceramic plate may be measured by the optical fibers using infrared pyrometry. The fiber optical thermocouples and/or other fiber optical temperature sensors may be used to measure the temperature of the ceramic plate and/or substrate at various regions. Each optical fiber that is a component of a fiber optic temperature sensor may be used to measure a temperature at a region of the ceramic plate and/or substrate. Optical fibers that are to measure a temperature of the substrate in some embodiments are routed through a channel or gas passage in the ceramic plate and directed at the substrate. In some embodiments, optical fibers may be used both for heating and for temperature measurement. For example, an optical fiber may be split into two portions at one end. A first portion may be routed to an optical heat source such as a laser diode and a second portion may be routed to a temperature sensor.

In some embodiments, one or more of the light sources 238C may be coupled by a sensor fiber 254 to a control sensor 255, such as a light receiver (e.g., photodiode). A control sensor 255 may be used to provide feedback to the optical controller 126 on a relative output of a control light source 238C (e.g., of light intensity or heat generation, for example). Optionally or in addition, one or more optical temperature sensors may be provided in one or more channels in the base 244 and/or ceramic plate 234 and coupled to a temperature measuring system 260 to enable localized temperature monitoring of an inside portion of the substrate support assembly 130. For example, the optical temperature sensor may be a fiber Bragg grating coupled to a spectrometer, which may be the temperature measuring system 260. A fiber multiplexer or other like component may be used to connect multiple optical temperature sensors to a single spectrometer. An optical temperature sensor may also be accomplished by other suitable means, such as by embedding a tip of an optical fiber in a suitable adhesive material (e.g., CERAMACAST 865 available from Aremco Products Inc. of Valley Cottage, N.Y.) and measuring the thermal radiation emitted by that material. Thermal measurement may be accomplished by coupling the optical fiber to an indium gallium arsenide photodiode. The optical fibers coupled to the optical temperature sensor may also be placed in a channel in the base 244 and/or ceramic plate 234. Any suitable temperature measuring system 260 may be used to interrogate the optical temperature sensor. Temperature measuring system 260 may interface with the temperature controller 128 and/or the optical controller 126 to provide temperature feedback. Optionally or additionally, thermal feedback by other methods, such as two or more RTDs on the substrate support assembly 130 may be used.

FIG. 3 shows one possible pattern of a plurality of optical fibers 235. Referring to FIG. 3, the cooling base 244 has the plurality of optical fibers 235 therein. Any suitable arrangement may be made for inclusion of the plurality of optical fibers 235. In one such example, a layout of the plurality of optical fibers 235 has between 200 to 500 input points on the back of the ceramic plate 234. Although a very specific pattern is depicted in FIG. 3 for illustrative purposes, other embodiments include different patterns (e.g., a symmetric pattern). It is to be understood that FIG. 3 illustrates one of many possibilities of total included optical fibers 235.

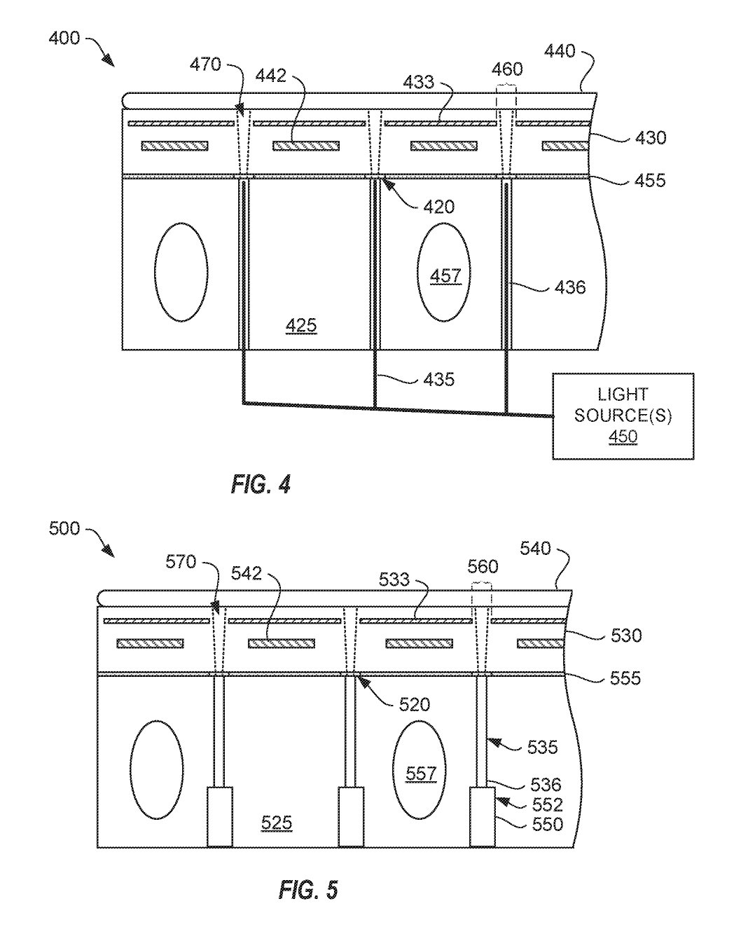

FIG. 4 illustrates a cross-sectional side view of a portion of a substrate support assembly 400 with light-based heating capability, in accordance with embodiments of the present invention. The substrate support assembly 400 includes a ceramic plate 430 coupled to a cooling base 425.

The ceramic plate 430 may be composed of a material that is substantially transparent to particular predetermined wavelengths of light. In one embodiment, the ceramic plate 430 is substantially transparent to light having a wavelength of about 0.25-5.0 microns in embodiments (e.g., in the near ultraviolet to mid-infrared wavelengths). As used herein, a material is substantially transparent to a wavelength of light if it has an optical transmittance of at least 75% at that wavelength of light. The ceramic plate may be aluminum nitride (AlN), aluminum oxy-nitride (AlON), sapphire, YAG or spinel in embodiments.

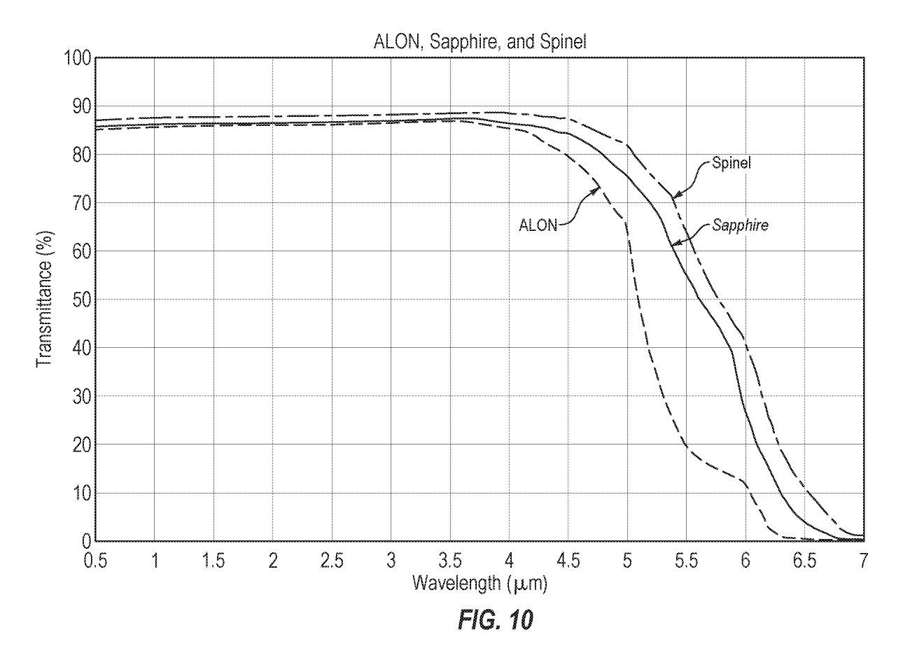

FIG. 10 is a chart illustrating transmittance of AlON, sapphire and spinal at wavelengths of 0.5-7 microns. As shown, each of AlON, spinel and sapphire have an optical transmittance of over 80% at wavelengths of 0.5-4.0. Additionally, these materials may have high transmittance down to wavelengths of about 0.25 microns and up to about 5.0 microns.

Referring back to FIG. 4, the ceramic plate 430 includes a top surface that supports a substrate 440 and a bottom surface that interfaces with the cooling base 425. The ceramic plate 430 in one embodiment includes resistive heating elements 442 and an electrode layer 433. The resistive heating elements 442 may heat the ceramic plate to a target temperature. Alternatively, the ceramic plate 430 may not include any resistive heating elements 442.

The electrode layer 433 may be a radio frequency (RF) electrode that may be used for directing plasma. For example, an RF signal may be applied to the electrode layer 433 during processing of a supported substrate. The electrode layer 433 may alternatively or additionally be a chucking electrode that is used to electrostatically chuck or secure the substrate 440. The electrode layer 433 may be molybdenum, aluminum, or another material with high electrical conductivity. In some embodiments, the electrode layer 433 is a fine mesh of metal lines having a thickness and/or width of about 25-125 microns. The electrode layer 433 may be referred to as an electrode mesh. Accordingly, in embodiments the ceramic plate 430 is an electrostatic chuck. The ceramic plate 430 may be used for Johnsen-R ahbek and/or Coulombic electrostatic chucking in embodiments.

The cooling base 425 (also referred to as a cooling plate) is a metal plate that is responsible for cooling the ceramic plate 430. The cooling base 425 includes multiple channels 457 that receive a coolant. The cooling base 425 may be, for example, aluminum or stainless steel. Other metals may also be used for the cooling base 425. In some embodiments, an RF signal is applied to the cooling base 425 during processing of a supported substrate. If an RF signal is to be applied to the cooling base 425, then a dielectric plate (e.g., made of AlN in an embodiment) may be disposed below the cooling base to electrically separate the cooling base 425 from ground and/or other components.

The cooling base 425 may be coupled to the ceramic plate 430 by a bond layer 455. The bond layer 455 may be a silicone bond, a metal bond, or another type of bond. The cooling base 425 may also be secured to the ceramic plate 430 by other coupling means in addition to or instead of bond layer 455. Examples of other coupling means include fasteners, springs that press the cooling base 425 against the ceramic plate 430, and so on.

The cooling base 425 includes multiple channels 436 to receive light carrying media such as optical fibers 435. The optical fibers (or other light carrying media) are inserted into the channels 436, and so are disposed inside of the cooling base 425.

The optical fibers 435 are coupled at one end to one or more light sources 450. The light sources 450 may be inside of a processing chamber that houses the substrate support assembly 400 or may be external to the processing chamber. The light sources may be, for example, laser diodes, light emitting diodes (LEDs), fiber lasers, or conventional light with a lens system. As a specific example, a high power 8.5 W 9xx nm Fiber-Coupled Diode Laser available from JDS Uniphase® Corporation is used. The light sources 450 may be configured to output light at a specific wavelength, where the ceramic plate 430 is substantially transparent to the light at that specific wavelength. In one embodiment, the light sources 450 are tuned to emit light having a wavelength of 0.25-5.0 microns. The light sources 450 may provide continuous or pulsed light. In an embodiment, approximately 1000 watts (e.g., in the range of 200 W to 2000 W) is used for heating through the optical fibers 435. In one such embodiment, in the case of a 250 fiber system, about 4 W is provided through each of the optical fibers 435.

The bond layer 455 may be a perforated bond layer that includes holes 420 or gaps in the bond layer at regions proximate to the channels 436. The bond layer 455 may not be transparent to light at the wavelengths of light emitted by the light sources 450. Accordingly, the bond layer may have holes 420 to permit passage of light 470 past the bond layer 455 without absorption by the bond layer 455.

The electrode layer 433 may also be a perforated layer that includes holes 460 or gaps in the electrode layer 433. The electrode layer 433 may not be transparent to light at the wavelengths of light emitted by the light sources 450. Accordingly, the electrode layer 433 may have holes 460 to permit passage of light 470 past the electrode layer 433 without absorption by the electrode layer 433. In some embodiments, instead of having holes to permit the light to pass through, the electrode layer 433 is a fine mesh of metal lines having a thickness and/or width of about 25-125 microns. The light 470 may pass through the mesh. In some embodiments, the electrode layer 433 is a mesh of metal lines that also has holes to permit the light 470 to pass unimpeded.

In some embodiments, the electrode layer 433 is composed of an optically transparent and electrically conductive material. For example, the electrode layer may be indium tin oxide (ITO), aluminum zinc oxide (AZO), or a similar material. In embodiments where the electrode layer 433 is optically transparent, the electrode layer 433 may not be perforated and may not include holes 460. Instead, light 470 may pass through the electrode layer 433 with minimal absorption by the electrode layer 433. In one embodiment, the electrode layer has a transmittance of at least 80% the predetermined wavelength of light output by the light source. For example, some ITO may have a transmittance of over 85% at wavelengths of about 0.5-1.0 micron. Accordingly, in some embodiments where ITO is used for the electrode layer 433 the light sources 450 may emit light at a wavelength of 0.5-1.0 micron.

As shown, optical fibers 435 are pointed at ceramic plate 430 and emit light 470 towards the ceramic plate 430. The ceramic plate is substantially transparent to the light 470 at the wavelengths used, and so the light 470 passes through the ceramic plate 430 with minimal absorption by the ceramic plate 430. The light 470 is then absorbed by the substrate 440 and directly heats the substrate 440 as a result of the absorption. Accordingly, the light may heat the substrate 440 with little to no heating of the ceramic plate 430.

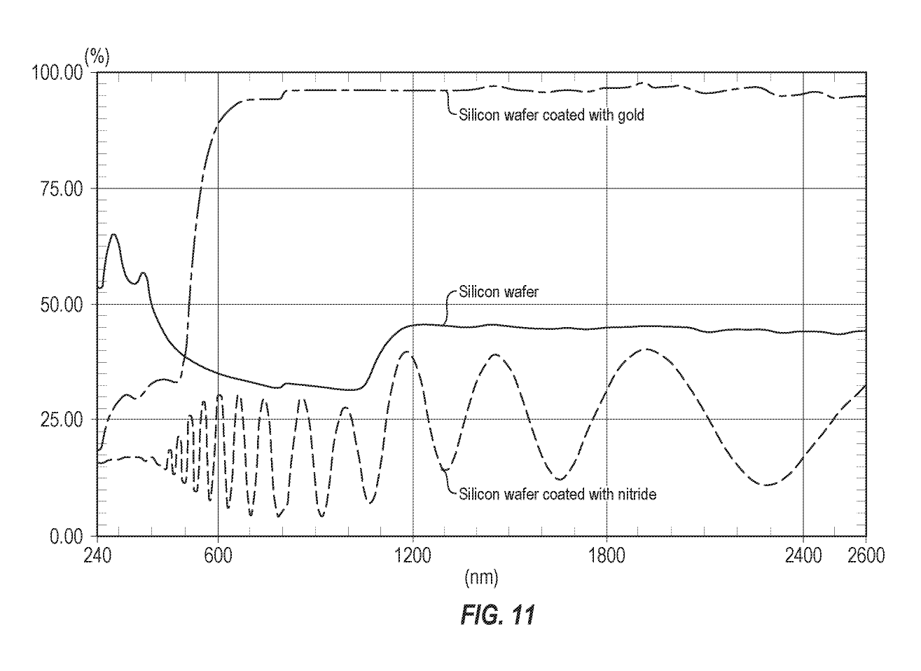

In some embodiments, the substrate 440 is a silicon substrate (e.g., a silicon wafer). Silicon may have a high absorption of light at wavelengths around 1 micron. In one embodiment, silicon has an absorption of over 60% at wavelengths of around 0.6-1.1 micron. FIG. 11 illustrates transmittance of silicon at wavelengths between 0.24 to 2.5 microns. As shown, the transmittance of silicon can be increased by coating the silicon with gold and can be decreased by coating the silicon with nitride.

In some embodiments, an optical coating may be included on the bottom surface of the ceramic plate 430 to increase the efficiency of light transmittance.

If three levels of temperature control are provided (e.g., a first level provided by the resistive heating elements 442, a second level provided by the cooling base 425, and a third level provided by the optical fibers 435), less than 1 degree non-uniformity over a 300 mm plate may be achieved. For example, in accordance with an embodiment of the present invention, the ceramic plate 430 has 1 or more (e.g., up to 8) resistive heating elements 442 along with cooling base 425 to a provide baseline temperature control. To provide fine-tuning of temperature distribution, a large number of light heating elements (e.g., light pipes, fiber optics, etc.) are position in the cooling base 425 to point at the ceramic plate 430 and the substrate 440 supported by the ceramic plate 430. To reduce RF-related non-uniformity, the fine-tuning light heaters are not resistance based. In an embodiment, etch processing with improved RF uniformity and/or improved temperature uniformity can be achieved.

FIG. 5 illustrates a cross-sectional side view of a portion of a substrate support assembly 500 with light-based heating capability, in accordance with embodiments of the present invention. The substrate support assembly 500 includes a ceramic plate 530 coupled to a cooling base 525. The ceramic plate 530 may be composed of any of the materials discussed with reference to ceramic plate 430. The ceramic plate 530 includes a top surface that supports a substrate 540 and a bottom surface that interfaces with the cooling base 525. The ceramic plate 530 in one embodiment includes resistive heating elements 542 and an electrode layer 533. The resistive heating elements 542 may heat the ceramic plate to a target temperature. Alternatively, the ceramic plate 530 may not include any resistive heating elements 542. The electrode layer 533 may be a radio frequency (RF) electrode that may be used for directing plasma. The electrode layer 533 may alternatively or additionally be a chucking electrode that is used to electrostatically chuck or secure the substrate 540. Accordingly, in embodiments the ceramic plate 530 is an electrostatic chuck. The ceramic plate 530 may be used for Johnsen-Rahbek and/or Coulombic electrostatic chucking in embodiments.

The cooling base 525 includes multiple channels 557 that receive a coolant. The cooling base 525 may be, for example, aluminum or stainless steel. Other metals may also be used for the cooling base 525.

The cooling base 525 may be coupled to the ceramic plate 530 by a bond layer 555. The bond layer 555 may be a silicone bond, a metal bond, or another type of bond. The cooling base 525 may also be secured to the ceramic plate 530 by other coupling means in addition to or instead of bond layer 555. Examples of other coupling means include fasteners, springs that press the cooling base 525 against the ceramic plate 530, and so on.

The cooling base 525 includes multiple channels 536 to receive light carrying media such as optical fibers 535. Alternatively, the channels 536 may be hollow channels, and the light carrying media may be air. The optical fibers (or other light carrying media) may be inserted into the channels 536, and so are disposed inside of the cooling base 525.

The cooling base 525 additionally includes one or more light sources 550 disposed in the cooling base 525. Channels 552 may be drilled into the cooling base 525, and the light sources 550 may be inserted into the channels 552. In one embodiment, each optical fiber 535 (or other light carrying medium) is coupled to a different light source 550. Alternatively, a light source 550 may be coupled to multiple optical fibers 535. The light sources 550 may correspond to any of the light sources 450 discussed above.

The bond layer 555 may be a perforated bond layer that includes holes 520 or gaps in the bond layer at regions proximate to the channels 536. The bond layer 555 may not be transparent to light at the wavelengths of light emitted by the light sources 550. Accordingly, the bond layer may have holes 520 to permit passage of light 570 past the bond layer 555 without absorption by the bond layer 555.

The electrode layer 533 may also be a perforated layer that includes holes 560 or gaps in the electrode layer 533. Alternatively or additionally the electrode layer 533 may be a mesh as described above. The electrode layer 533 may not be transparent to light at the wavelengths of light emitted by the light sources 550. Accordingly, the electrode layer 533 may have holes 560 and/or a mesh to permit passage of light 570 past the electrode layer 533 without absorption by the electrode layer 533.

In some embodiments, the electrode layer 533 is composed of an optically transparent and electrically conductive material. For example, the electrode layer may be indium tin oxide (ITO), aluminum zinc oxide (AZO), or a similar material. In embodiments where the electrode layer 533 is optically transparent, the electrode layer 533 may not be perforated and may not include holes 560. Instead, light 570 may pass through the electrode layer 533 with minimal absorption by the electrode layer 533. For example, some ITO may have a transmittance of over 85% at wavelengths of about 0.5-1.0 micron. Accordingly, in some embodiments where ITO is used for the electrode layer 533 the light sources 550 may emit light at a wavelength of 0.5-1.0 micron.

As shown, optical fibers 535 are pointed at ceramic plate 530 and emit light 570 towards the ceramic plate 530. The ceramic plate is substantially transparent to the light 570 at the wavelengths used, and so the light 570 passes through the ceramic plate 530 with minimal absorption by the ceramic plate 530. The light 570 is then absorbed by the substrate 540 and directly heats the substrate 540 as a result of the absorption. Accordingly, the light may heat the substrate 540 with little to no heating of the ceramic plate 530.

In some embodiments, the substrate 540 is a silicon substrate (e.g., a silicon wafer). Silicon may have a high absorption of light at wavelengths around 1 micron. In one embodiment, silicon has an absorption of over 60% at wavelengths of around 0.6-1.1 micron.

In some embodiments, an optical coating may be included on the bottom surface of the ceramic plate 530 to increase the efficiency of light transmittance.

If three levels of temperature control are provided (e.g., a first level provided by the resistive heating elements 542, a second level provided by the cooling base 525, and a third level provided by the optical fibers 535), less than 1 degree non-uniformity over a 300 mm plate may be achieved. For example, in accordance with an embodiment of the present invention, the ceramic plate 530 has 1 or more (e.g., up to 8) resistive heating elements 542 along with cooling base 525 to a provide baseline temperature control. To provide fine-tuning of temperature distribution, a large number of light heating elements (e.g., light pipes, fiber optics, etc.) are position in the cooling base 525 to point at the ceramic plate 530 and the substrate 540 supported by the ceramic plate 530. To reduce RF-related non-uniformity, the fine-tuning light heaters are not resistance based. In an embodiment, etch processing with improved RF uniformity and/or improved temperature uniformity can be achieved.

In some embodiments, substrate support assemblies 400 and 500 are used for processes where the substrate is repeatedly heated to a first target temperature and cooled to a second lower target temperature during processing. In embodiments, the first target temperature is around 120-400° C. In further embodiments, the first target temperature is around 120-150° C. The substrate support assemblies 400, 500 may facilitate such processes by using the cooling base 425, 525 to maintain the ceramic plate 430, 530 at or below the second target temperature. The resistive heating elements may not be included in the ceramic plate 430, 530 and/or may not be used in these embodiments. The optical fibers may emit light that passes through the ceramic plate and heats the substrate 440, 540 at a rapid heating rate of up to about 20° C./s. The optical heating may be performed while the electrode 433, 533 is deactivated so as to minimize thermal contact between the substrate 440, 540 and the ceramic plate 430, 530.

After the substrate 440, 540 has been heated to the first target temperature, the electrode 433, 533 may be activated. Additionally, helium or another thermally conductive gas may be pumped into a region between the substrate 440, 540 and the upper surface of the ceramic plate 430, 530 through a gas passage. The electrode 433, 533 may chuck the substrate 440, 540, pulling the substrate tightly against the ceramic plate. A combination of the chucking and the helium may thermally couple the substrate to the ceramic plate. The ceramic plate 430, 530, which is at or below the second target temperature, then rapidly cools off the substrate 440, 540 at a rate of up to about 20° C./s.

Once the substrate 440, 540 has reached the second target temperature, the electrode 433, 533 may be deactivated and/or the helium may be pumped out of the region between the ceramic plate and the substrate to again thermally decouple the substrate from the ceramic plate. This process may be repeated numerous times in a single process.

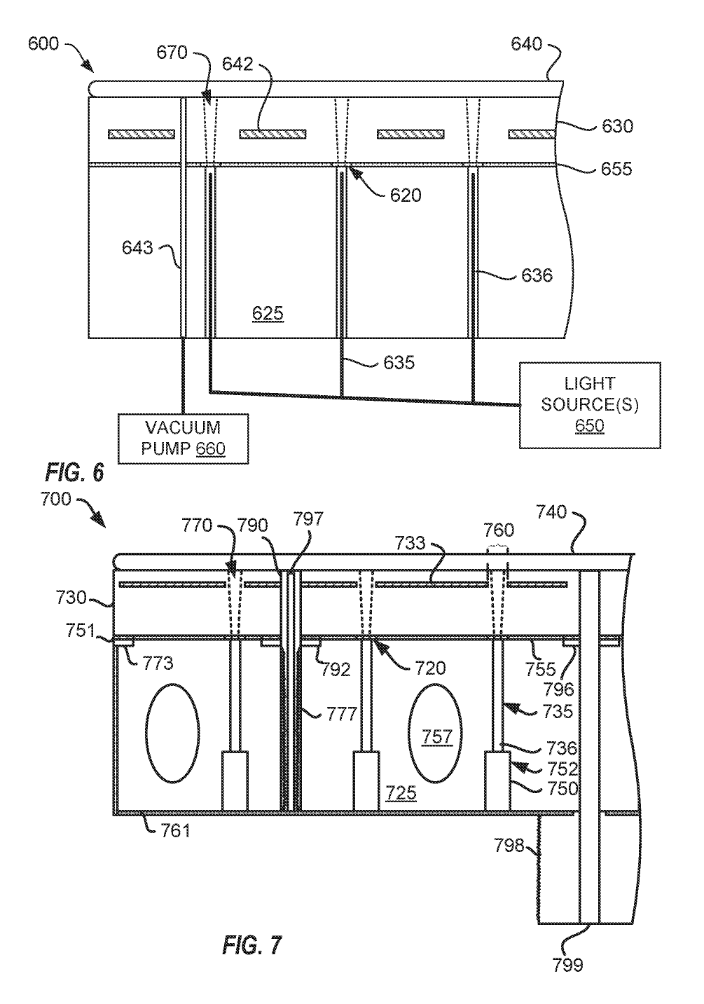

FIG. 6 illustrates a cross-sectional side view of a portion of a substrate support assembly 600 with light-based heating capability, in accordance with embodiments of the present invention. The substrate support assembly 600 includes a ceramic plate 630 coupled to a base 625. The ceramic plate 630 may be composed of any of the materials discussed with reference to ceramic plate 430. The ceramic plate 630 includes a top surface that supports a substrate 640 and a bottom surface that interfaces with the base 625. The ceramic plate 630 in one embodiment includes resistive heating elements 642. The resistive heating elements 642 may heat the ceramic plate to a target temperature. Alternatively, the ceramic plate 630 may not include any resistive heating elements 642.

The base 625 may be a cooling base or may not be a cooling base. If the base 625 is a cooling base, then it may be substantially similar to cooling base 425. In some embodiments, substrate support assembly 600 does not include a cooling base. In some such embodiments, base 625 may be a ceramic base or a metal base that secures optical fibers 635. A ceramic base may be made of AN, Al₂O₃ or other ceramics. A metal base may be stainless steel, aluminum, or other metals.

The base 625 may be coupled to the ceramic plate 630 by a bond layer 655. The bond layer 655 may be a silicone bond, a metal bond, or another type of bond. If the base is a ceramic base, then the bond layer 655 may be a diffusion bond that may be formed by heating and compressing the ceramic plate 630 against the base 625. The base 625 may also be secured to the ceramic plate 630 by other coupling means in addition to or instead of bond layer 655. Examples of other coupling means include fasteners, springs that press the base 625 against the ceramic plate 630, and so on.

The base 625 includes multiple channels 636 to receive light carrying media such as optical fibers 635. The optical fibers (or other light carrying media) may be inserted into the channels 636, and so are disposed inside of the base 625.

The optical fibers 635 are coupled at one end to one or more light sources 650. The light sources 650 may be inside of a processing chamber that houses the substrate support assembly 600 or may be external to the processing chamber. The light sources 650 may be, for example, laser diodes, light emitting diodes (LEDs), fiber lasers, or conventional light with a lens system. As a specific example, a high power 8.5 W 9xx nm Fiber-Coupled Diode Laser available from JDS Uniphase® Corporation is used. The light sources 650 may be configured to output light at a specific wavelength, where the ceramic plate 630 is substantially transparent to the light at that specific wavelength. In one embodiment, the light sources 650 are tuned to emit light having a wavelength of 0.25-5.0 microns. The light sources 650 may provide continuous or pulsed light. In an embodiment, approximately 1000 watts (e.g., in the range of 200 W to 2000 W) is used for heating through the optical fibers 635. In one such embodiment, in the case of a 250 fiber system, about 4 W is provided through each of the optical fibers 635.

In alternative embodiments, the base 625 may include the one or more light sources 650 disposed in the base 625. Channels may be drilled into the base 625, and the light sources 650 may be inserted into the channels.

In one embodiment, each optical fiber 635 (or other light carrying medium) is coupled to a different light source 650. Alternatively, a light source 650 may be coupled to multiple optical fibers 635.

In some embodiments, the bond layer 655 may be a perforated bond layer that includes holes 620 or gaps in the bond layer at regions proximate to the channels 636. The bond layer 655 may not be transparent to light at the wavelengths of light emitted by the light sources 650. Accordingly, the bond layer may have holes 620 to permit passage of light 670 past the bond layer 655 without absorption by the bond layer 655. In some embodiments, such as embodiments where the bond layer 655 is a diffusion bond, the bond layer 655 may not be perforated.

As shown, optical fibers 635 are pointed at ceramic plate 630 and emit light 670 towards the ceramic plate 630. The ceramic plate is substantially transparent to the light 670 at the wavelengths used, and so the light 670 passes through the ceramic plate 630 with minimal absorption by the ceramic plate 630. The light 670 is then absorbed by the substrate 640 and directly heats the substrate 640 as a result of the absorption. Accordingly, the light may heat the substrate 640 with little to no heating of the ceramic plate 630.

In some embodiments, the substrate 640 is a silicon substrate (e.g., a silicon wafer). Silicon may have a high absorption of light at wavelengths around 1 micron. In one embodiment, silicon has an absorption of over 60% at wavelengths of around 0.6-1.1 micron.

In some embodiments, an optical coating may be included on the bottom surface of the ceramic plate 630 to increase the efficiency of light transmittance.

Ceramic plate 630 and base 625 additionally include a gas channel (also referred to as a gas evacuation line) 643. The gas channel may couple to a vacuum pump 660, which may evacuate air and/or gas from a region between the substrate 640 and the top surface of the ceramic plate 630 and create a vacuum in the region. The vacuum pump 660 may secure the substrate to the ceramic plate 630. Accordingly, ceramic plate 630 may be a vacuum chuck in some embodiments. Additionally, the vacuum may act as a thermal break and decrease thermal coupling between the ceramic plate 630 and the substrate 640.

Substrate support assembly 600 may be used for processes where a substrate 640 is to be heated to high temperatures of 200° C. or higher (e.g., up to 650° C. in some embodiments). Since the ceramic plate 630 may absorb little of the energy from light 670, there may be a large temperature delta between the substrate 640 and the ceramic plate 630. By thermally decoupling the substrate 640 from the ceramic plate 630, radiant heating of the ceramic plate 630 by the heated substrate 640 may be reduced.

Depending on the temperature that the substrate is heated to, a delta temperature between the substrate 640 and the ceramic plate 630 may cause the ceramic plate 630 to heat at a rate that causes thermal stress that could result in cracking of the ceramic plate 630. The thermal stress can be mitigated by using resistive heating elements 642 to heat the ceramic plate 630 to a temperature that is at or below the temperature to which the substrate 640 is heated. By heating up the ceramic plate 630 using the resistive heating elements, the temperature delta between the substrate 640 and the ceramic plate can be reduced to a level that will not cause cracking.

Substrate support assembly 600 may be particularly useful for processes that use fluorine and that are to be performed at or above 450° C. At and above 450° C. AlN reacts with fluorine to form AlF₃. Substrate support assembly 600 enables the substrate to be heated at or above 450° C. without heating the ceramic plate 630 (which may be AlN in some embodiments) to 450° C. Accordingly, embodiments enable high temperature processes that use fluorine to be performed without the formation of AlF₃ in the substrate support.

An optical transmittance of any of the ceramic plates 430, 530, 630 can be tailored based an amount of energy absorption that is useful for the ceramic plate. By adjusting the energy absorption of the ceramic plate at particular wavelengths, light from optical fibers can be used to heat the ceramic plates 430-630 a modest amount. For example, the ceramic plate optical absorption can be tuned to cause the ceramic plate to absorb 20-30% of energy output by the optical fiber. This may cause the ceramic plate to heat, for example, to a temperature that is about 20-50% of the temperature that the substrate is heated to. Ceramic plates 430, 530, 630 may each have thicknesses of about 5-10 mm in embodiments. In one embodiment, there is less than 3% physical contact between an upper surface of the ceramic plates 430, 530, 630 and the supported substrates.

FIG. 7 illustrates a cross-sectional side view of a portion of a substrate support assembly 700 with light-based heating capability, in accordance with embodiments of the present invention. The substrate support assembly 700 may be used, for example, for metal deposition product (MDP) chambers. The substrate support assembly 700 includes a ceramic plate 730 coupled to a cooling base 725. The ceramic plate 730 may be composed of any of the materials discussed with reference to ceramic plate 430. The ceramic plate 730 includes a top surface that supports a substrate 740 and a bottom surface that interfaces with the cooling base 725. The ceramic plate 730 in one embodiment includes an electrode layer 733. The electrode layer 733 may be a radio frequency (RF) electrode that may be used for directing plasma. The electrode layer 733 may alternatively or additionally be a chucking electrode that is used to electrostatically chuck or secure the substrate 740. Accordingly, in embodiments the ceramic plate 730 is an electrostatic chuck. The ceramic plate 730 may be used for Johnsen-Rahbck and/or Coulombic electrostatic chucking in embodiments.

The cooling base 725 includes multiple channels 757 that receive a coolant. The cooling base 725 may be, for example, aluminum or AlSiSiC composite or stainless steel. Other metals may also be used for the cooling base 725.

The cooling base 725 may be coupled to the ceramic plate 730 by a bond layer 755. The bond layer 755 may be a silicone bond, a metal bond, or another type of bond. If the cooling base is coupled to the ceramic plate 730 by bond layer 755, then the ceramic plate 730 may have a thickness of 5-10 mm in embodiments. In one embodiment, the ceramic plate 730 has a thickness of about 5 mm.

The cooling base 725 may also be secured to the ceramic plate 730 by other coupling means in addition to or instead of bond layer 755. Examples of other coupling means include fasteners, springs that press the cooling base 725 against the ceramic plate 730, and so on. If the cooling base 725 is not bonded to ceramic plate 730, then a graphoil layer may be used instead of the bond layer 755 at the junction between the cooling base 725 and the ceramic plate 730 to improve a thermal conductivity at the junction. If the graphoil layer is used instead of a bond layer, then the ceramic plate 730 may have a thickness of about 10-15 mm in embodiments. In one embodiment, the ceramic plate has a thickness of 11 mm.

The substrate support assembly 700 further includes multiple rings 773, 792, 796 bonded to the bottom surface of the ceramic plate 730 by a bond 751. The bond 751 may be a silicone bond, a braze, or another bond. The rings include an outer ring 773 that is bonded to the ceramic plate 730 at an outer perimeter of the ceramic plate 730, an additional ring 792 bonded to the ceramic plate 730 around lift pin holes 790 and an additional ring 796 bonded to the ceramic plate 730 around a gas channel 799. The rings 773, 792, 796 may be kovar, molybdenum, or another material. The rings 773, 792, 796 may be bonded to the ceramic plate 730 by brazing. The rings 773, 792, 796 may also be bonded to the cooling base 725 by welding such as e-beam welding.

The cooling base 725 includes multiple channels 736 to receive light carrying media such as optical fibers 735. Alternatively, the channels 736 may be hollow channels, and the light carrying media 735 may be air. The optical fibers (or other light carrying media) may be inserted into the channels 736, and so are disposed inside of the cooling base 725.

The cooling base 725 additionally includes one or more light sources 750 disposed in the cooling base 725. Channels 752 may be drilled into the cooling base 725, and the light sources 750 may be inserted into the channels 752. Alternatively, the light source (or multiple light sources) 750 may be external to the cooling base 725. In one embodiment, each optical fiber 735 (or other light carrying medium) is coupled to a different light source 750. Alternatively, a light source 750 may be coupled to multiple optical fibers 735. The light sources 750 may correspond to any of the light sources 450 discussed above.

The bond layer 755 or graphoil layer may be a perforated layer that includes holes 720 or gaps in the layer at regions proximate to the channels 736. The bond layer 755 or graphoil layer may not be transparent to light at the wavelengths of light emitted by the light sources 750. Accordingly, the bond layer or graphoil layer may have holes 720 to permit passage of light 770 past the bond layer 755 or graphoil layer without absorption by the bond layer 755 or graphoil layer.

The electrode layer 733 may also be a perforated layer that includes holes 760 or gaps in the electrode layer 733. Alternatively or additionally the electrode layer 733 may be a mesh as described above. The electrode layer 733 may not be transparent to light at the wavelengths of light emitted by the light sources 750. Accordingly, the electrode layer 733 may have holes 760 and/or a mesh to permit passage of light 770 past the electrode layer 733 without absorption by the electrode layer 733.

In some embodiments, the electrode layer 733 is composed of an optically transparent and electrically conductive material. For example, the electrode layer may be indium tin oxide (ITO), aluminum zinc oxide (AZO), or a similar material. In embodiments where the electrode layer 733 is optically transparent, the electrode layer 733 may not be perforated and may not include holes 760. Instead, light 770 may pass through the electrode layer 733 with minimal absorption by the electrode layer 733. For example, some ITO may have a transmittance of over 85% at wavelengths of about 0.5-1.0 micron. Accordingly, in some embodiments where ITO is used for the electrode layer 733 the light sources 750 may emit light at a wavelength of 0.5-1.0 micron.

A metal backside cover 761 may cover side walls and a bottom of the cooling base 725. The metal backside cover 761 may be welded (e.g., e-beam welded) to the ring 773 at the periphery of the cooling base 725. A metal tube or metal bellows 798 may be welded to the metal backside cover 761, and may seal the gas channel 799 from exposure to the environment of the chamber. The metal tube or metal bellows 798 may be stainless steel or another metal.

The ceramic plate 730 and cooling base 725 both include lift pin holes 790. Lift pins 797 are disposed inside of the lift pin holes 790. A metal tube or metal bellows 777 may be inserted into the lift pin holes 790 and bonded to the metal backside cover 761 and to the rings 792. The metal tube or metal bellows 777 may permit the region inside of the bellows to be exposed to the environment of a processing chamber and protect a remainder of the substrate support assembly interior from exposure to the environment of the processing chamber.

Use of the metal backside cover 761, metal tube or metal bellows 777 and metal tube or metal bellows 798 enables the cooling plate to have a diameter that is similar to the diameter of the substrate 740.

As shown, optical fibers 735 are pointed at ceramic plate 730 and emit light 770 towards the ceramic plate 730. The ceramic plate is substantially transparent to the light 770 at the wavelengths used, and so the light 770 passes through the ceramic plate 730 with minimal absorption by the ceramic plate 730. The light 770 is then absorbed by the substrate 740 and directly heats the substrate 740 as a result of the absorption. Accordingly, the light may heat the substrate 740 with little to no heating of the ceramic plate 730.

In some embodiments, the substrate 740 is a silicon substrate (e.g., a silicon wafer). Silicon may have a high absorption of light at wavelengths around 1 micron. In one embodiment, silicon has an absorption of over 60% at wavelengths of around 0.6-1.1 micron. In some embodiments, an optical coating may be included on the bottom surface of the ceramic plate 730 to increase the efficiency of light transmittance.

In some embodiments, the substrate support assembly 700 is able to both heat and cool the substrate 740. The substrate may be heated by direct optical heating using light energy delivered by the optical fibers 735 (or other optical transmission media). The substrate 740 may be cooled by maintaining the ceramic plate 730 and cooling base 725 at a target temperature and thermally coupling the substrate 740 to the ceramic plate 730.

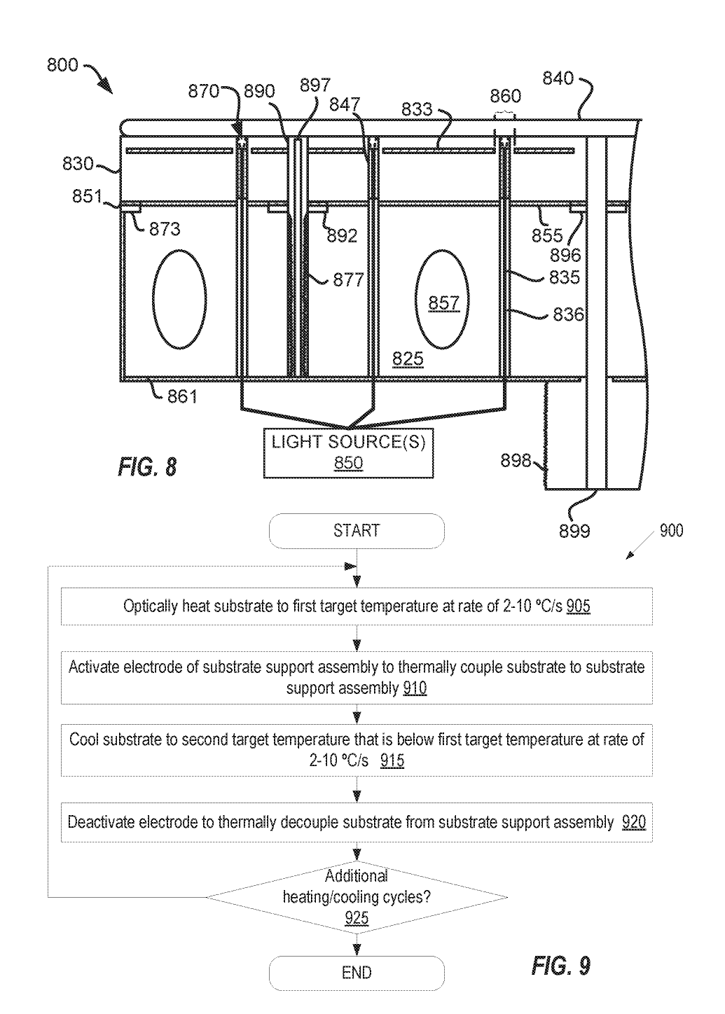

FIG. 8 illustrates a cross-sectional side view of a portion of a substrate support assembly 800 with light-based heating capability, in accordance with embodiments of the present invention. The substrate support assembly 800 may be used, for example, for metal deposition product (MDP) chambers. The substrate support assembly 800 includes a ceramic plate 830 coupled to a cooling base 825. The ceramic plate 830 may be composed of any of the materials discussed with reference to ceramic plate 430, and may be substantially transparent to wavelengths of light used for optical heating in embodiments. Alternately, the ceramic plate 830 may be opaque to wavelengths of light used for optical heating of substrates. For example, ceramic plate 830 may be AlN, Al₂O₃, or other materials.

The ceramic plate 830 includes a top surface that supports a substrate 840 and a bottom surface that interfaces with the cooling base 825. The ceramic plate 830 in one embodiment includes an electrode layer 833. The electrode layer 833 may be powered with a radio frequency (RF) power supply that may be used for directing plasma. Typical RF used is 2 MHz to 160 MHz or typically 13.56 MHz. Lower frequencies such as 400 KHz also could be used. The electrode layer 833 is also additionally a chucking electrode that is used to electrostatically chuck or secure the substrate 840 by using high voltage DC power supply in embodiments. The ceramic plate 830 has multiple channels 836 to allow light carrying medium 835 to go through the ceramic plate and to optionally be flush with the top surface of the ceramic plate 830. Accordingly, in embodiments the ceramic plate 830 is an electrostatic chuck. The ceramic plate 830 may be used for Johnsen-Rahbek and/or Coulombic electrostatic chucking in embodiments.

The cooling base 825 includes multiple channels 857 that receive a coolant. The cooling base 825 may be, for example, aluminum, AlSiSiC composite or stainless steel. Other metals may also be used for the cooling base 825.

The cooling base 825 may be coupled to the ceramic plate 830 by a bond layer 855. The bond layer 855 may be a silicone bond, a metal bond, or another type of bond. If the cooling base is coupled to the ceramic plate 830 by bond layer 855, then the ceramic plate 830 may have a thickness of 5-17 mm in embodiments. In one embodiment, the ceramic plate 830 has a thickness of about 5 mm.

The cooling base 825 may also be secured to the ceramic plate 830 by other coupling means in addition to or instead of bond layer 855. Examples of other coupling means include fasteners, springs that press the cooling base 825 against the ceramic plate 830, and so on. If the cooling base 825 is not bonded to ceramic plate 830 (e.g., if the cooling plate is spring loaded and pressed against the ceramic plate using springs), then a graphoil layer may be used instead of the bond layer 855 at the junction between the cooling base 825 and the ceramic plate 830 to improve a thermal conductivity at the junction. If the graphoil layer is used instead of a bond layer, then the ceramic plate 830 may have a thickness of about 10-15 mm in embodiments. In one embodiment, the ceramic plate has a thickness of 11 mm. The bond layer 855 or graphoil layer may be a perforated bond layer that includes holes or gaps in the bond layer or graphoil layer at regions proximate to the channels.

The substrate support assembly 800 further includes multiple rings 873, 892, 896 bonded to the bottom surface of the ceramic plate 830 by a bond 851. The bond 851 may be a silicone bond, a braze, or another bond. The rings include an outer ring 873 that is bonded to the ceramic plate 830 at an outer perimeter of the ceramic plate 830, an additional ring 892 bonded to the ceramic plate 830 around lift pin holes 890 and an additional ring 896 bonded to the ceramic plate 830 around a gas channel 899. The rings 873, 892, 896 may be kovar, molybdenum, stainless steel or another material. The rings 873, 892, 896 may be bonded to the ceramic plate 830 by brazing. The rings 873, 892, 896 may also be bonded to the cooling base 825 by welding such as e-beam welding.

The cooling base 825 and ceramic plate 830 both include multiple channels 836 to receive light carrying media such as optical fibers 835. Alternatively, the channels 836 may be hollow channels, and the light carrying media 835 may be air. The optical fibers (or other light carrying media) may be inserted into the channels 836, and so are disposed inside of the cooling base 825 and inside of the ceramic plate 830. Since the channels 836 extend through the ceramic plate 830, the ceramic plate 830 may be composed of a material that would absorb the light emitted by the optical fibers 835.

The optical fibers 835 terminate at a first end near or at a top surface of the ceramic plate 830 and at a second end at one or more light sources 850. A backside of the substrate support assembly may be exposed to air and/or atmospheric pressure while a top of the substrate support assembly (e.g., between the top surface of the ceramic plate 830 and the substrate 840) may be maintained at a vacuum. In embodiments the optical fibers 835 are attached to the ceramic plate 830 and/or to the cooling base 825 in a manner that provides a seal. The optical fiber 835 may be attached to the ceramic plate and/or cooling base along some or all of the length of the channels 836. The attachment may be a bond 847 that fills in any voids between the optical fibers 835 and the channels 836 and bonds the optical fibers 835 to walls of the channels. The bond 847 may be, for example, a braze or glue. The bond 847 in some embodiments is at or near an end of the optical fiber. The bond 847 may or may not extend from the end further into the channels 836. The attachment may also be a coupler or other fixture.

The light sources may be external to the cooling base 825. Additionally, the light sources 850 may be internal to a processing chamber or external to the processing chamber. Alternatively, the cooling base 825 may include the one or more light sources 850 disposed in the cooling base 825. Channels may be drilled into the cooling base 825, and the light sources 850 may be inserted into the channels 836. In one embodiment, each optical fiber 835 (or other light carrying medium) is coupled to a different light source 850. Alternatively, a light source 850 may be coupled to multiple optical fibers 835. The light sources 850 may correspond to any of the light sources 450 discussed above. The light sources 850 may emit light at any of the various wavelengths previously recited herein. Additionally, the light sources 850 may emit light at a wider range of wavelengths than previously indicated since absorption by the ceramic plate is not a concern.

The electrode layer 833 may be a perforated layer that includes holes 860 or gaps in the electrode layer 833. Alternatively or additionally the electrode layer 833 may be a mesh as described above. In some embodiments, the electrode layer 833 is a solid or mesh layer prior to formation of the channels 836 and the channels 836 are bored through the electrode layer 833.

A metal backside cover 861 may cover side walls and a bottom of the cooling base 825. The metal backside cover 861 may be welded (e.g., e-beam welded) to the ring 873 at the periphery of the cooling base 825. A metal tube or metal bellows 898 may be welded to the metal backside cover 861, and may seal the gas channel 899 from exposure to the environment of the chamber. The metal tube or metal bellows 898 may be stainless steel or another metal.

Use of the metal backside cover 861, metal tube or metal bellows 877 and metal tube or metal bellows 898 enables the cooling plate to have a diameter that is similar to the diameter of the substrate 840.

The ceramic plate 830 and cooling base 825 both include lift pin holes 890. Lift pins 897 are disposed inside of the lift pin holes 890. A metal tube or metal bellows 877 may be inserted into the lift pin holes 890 and bonded to the metal backside cover 861 and to the rings 892. The metal tube or metal bellows 877 may permit the region inside of the bellows to be exposed to the environment of a processing chamber and protect a remainder of the substrate support assembly interior from exposure to the environment of the processing chamber.

As shown, optical fibers 835 are disposed inside ceramic plate 830 and directed toward substrate 840. The optical fibers 835 emit light 870 towards the substrate 840. The light 870 is then absorbed by the substrate 840 and directly heats the substrate 840 as a result of the absorption. Accordingly, the light may heat the substrate 840 with little to no heating of the ceramic plate 830.

In some embodiments, the substrate 840 is a silicon substrate (e.g., a silicon wafer). Silicon may have a high absorption of light at wavelengths around 1 micron. In one embodiment, silicon has an absorption of over 60% at wavelengths of around 0.6-1.1 micron. In some embodiments, an optical coating may be included on the bottom surface of the ceramic plate 830 to increase the efficiency of light transmittance.

In some embodiments, the substrate support assembly 800 is able to both heat and cool the substrate 840. The substrate may be heated by direct optical heating using light energy delivered by the optical fibers 835 (or other optical transmission media). The substrate 840 may be cooled by maintaining the ceramic plate 830 and cooling base 825 at a target temperature and thermally coupling the substrate 840 to the ceramic plate 830.

In some embodiments, substrate support assemblies 700 and 800 are used for processes where the substrate is repeatedly heated to a first target temperature and cooled to a second lower target temperature during processing. In embodiments, the first target temperature is around 120-400° C. In further embodiments, the first target temperature is around 120-150° C. The substrate support assemblies 700, 800 may facilitate such processes by using the cooling base 725, 825 to maintain the ceramic plate 730, 830 at or below the second target temperature. The resistive heating elements may not be included in the ceramic plate 730, 830 and/or may not be used in these embodiments. The optical fibers may emit light that passes through the ceramic plate and heats the substrate 740, 840 at a rapid heating rate of up to about 20° C./s. The optical heating may be performed while the electrode 733, 833 is deactivated so as to minimize thermal contact between the substrate 740, 840 and the ceramic plate 730, 830. In some embodiments, the optical heating is performed while lift pins 797, 897 are extended and lifting the substrate 740, 840 above the ceramic plate 730, 840 (e.g., so that there is a separation between the top surface of the ceramic plate 730, 830 and the substrate 740, 840. Lifting the wafer on lift pins 797,897 may provide better temperature uniformity due to larger optical spot on substrate.

After the substrate 740, 840 has been heated to the first target temperature, the electrode 733, 833 may be activated. Additionally, helium, argon or another thermally conductive gas may be pumped into a region between the substrate 440, 540 and the upper surface of the ceramic plate 430, 530 through a gas passage. If the heating was performed while the lift pins 797, 897 were extended, then the lift pins 797, 897 may be retracted prior to activating the electrode 733, 833. The electrode 733, 833 may chuck the substrate 740, 840, pulling the substrate tightly against the ceramic plate. A combination of the chucking and the helium may thermally couple the substrate to the ceramic plate. The ceramic plate 730, 830, which is at or below the second target temperature, then rapidly cools off the substrate 740, 840 at a rate of up to about 20° C./s.

Once the substrate 740, 840 has reached the second target temperature, the electrode 733, 833 may be deactivated, the lift pins 797, 897 may be extended and/or the helium may be pumped out of the region between the ceramic plate and the substrate to again thermally decouple the substrate from the ceramic plate. This process may be repeated numerous times in a single process. In an example process a metal film is deposited on the substrate, then the substrate is heated, then the substrate is cooled. These cycles (deposit metal, heat, cool) could be repeated numerous times in a single process.

FIG. 9 illustrates a flowchart depicting a method 900 of rapidly heating and cooling a substrate during a manufacturing process, in accordance with embodiments of the present invention. Method 900 may be performed by a substrate support assembly in combination with one or more control systems that may control light emitted by light sources and/or electrodes of the substrate support assembly. The control systems may be coupled to additional systems that may include a recipe for performing a process. The recipe may specify target temperatures, process times, gas flow rates, and so on. Method 900 may be performed as part of a deposition process, an etch process, an implant process, and so on. In embodiments method 900 may be performed using substrate support assembly 130, substrate support assembly 400 or substrate support assembly 500.

At block 905 of method 900 a substrate supported by the substrate support assembly is optically heated to a first target temperature at a rate of about 2-20° C./s. In examples, the substrate is heated at a rate of 3° C./s , at a rate of 5° C./s , at a rate of 7° C./s , at a rate of 9° C./s , at a rate of 10° C./s, at a rate of 15° C./s, or at a rate of 20° C./s. The optical heating may be performed by directing light having a particular wavelength through optical fibers and then through an electrostatic chuck (also referred to as a ceramic plate) of the substrate support assembly onto the substrate. The electrostatic chuck may be substantially transparent to the light at the particular wavelength in some embodiments, and so the light may pass through the electrostatic chuck and be absorbed by the substrate. In some embodiments, the optical fibers extend into channels in the electrostatic chuck and shine directly on the substrate. The channels in the electrostatic chuck may be through channels. Vacuum may be maintained by glue or a bond between the light carrying medium and the ceramic plate (e.g., walls of the channel in the ceramic plate into which the light carrying medium is inserted).

The first target temperature may be between 120 and 400° C. Example target temperatures include 120° C., 130° C., 140° C., 150° C., 160° C., 170° C., 180° C., 200° C., 350° C., 400° C., etc. A chucking electrode of the substrate support assembly (e.g., of an electrostatic chuck in the substrate support assembly) may be deactivated during the heating to minimize a thermal contact between the substrate and the substrate support assembly. It may be beneficial to thermally decouple the substrate from the electrostatic chuck to minimize heat transfer from the substrate (which is heated) to the electrostatic chuck (which is not heated or minimally heated). In some embodiments, the optical heating is performed while lift pins are extended through the substrate support assembly. The lift pins may raise the support above the substrate support assembly to facilitate thermal decoupling of the substrate from the substrate support assembly during heating.

At block 910, the electrode of the substrate support assembly (e.g., of the electrostatic chuck) is activated and lights that were providing light through the optical fibers are deactivated. Additionally, if the lift pins were extended to improve thermal decoupling between the electrostatic chuck and the substrate, then the lift pins may be retracted. Activation of the electrode “chucks” the electrode, pulling the electrode tightly against the substrate support assembly and sealing a region between the substrate and the substrate support assembly. Helium gas or other backside gas may also be flowed into the region between a top surface of the substrate support assembly (e.g., a top surface of the electrostatic chuck) and a bottom surface of the substrate. Activation of the electrode and/or pumping of helium gas into the region between the substrate and the substrate support assembly may thermally couple the substrate to the substrate support assembly.

The substrate support assembly may be maintained at or below a second target temperature that is lower than the first target temperature. The second target temperature may be, for example, anywhere from 20° C. (e.g., room temperature) to 100° C. By thermally coupling the substrate to the substrate support assembly, heat energy from the substrate may quickly dissipate into the substrate support assembly. Accordingly, at block 915 the substrate is cooled to the second target temperature. The substrate support assembly may have a much larger thermal mass than the substrate, which may facilitate quick cooling of the substrate by the substrate support assembly. In one embodiment, the substrate cools at a rate of about 2-20° C.

Once the substrate has cooled to the second target temperature, at block 920 the electrode is deactivated. The helium (or other backside gas) may be evacuated from the region between the substrate and the substrate support assembly. Alternatively, the helium gas may be allowed to naturally dissipate due to a loss of a seal between the substrate and the substrate support assembly. Deactivation of the electrode and/or evacuation of the helium gas may thermally decouple the substrate from the substrate support assembly.

In an alternative implementation, at block 920 the electrode may not be deactivated and/or the helium may not be evacuated from the region between the substrate and the substrate support assembly. This may facilitate quicker processing times, but may cause heat from the substrate to drain into the substrate support assembly during heating. In such implementations, additional energy may be supplied to the substrate (in the form of light) to compensate for the heat loss to the substrate support assembly.

The rate at which heat energy is transferred from the substrate to the substrate support assembly may depend at least partially on a thermal conductivity of the ceramic plate (electrostatic chuck) of the substrate support assembly. For example sapphire has a thermal conductivity of approximately 30 Watts per meter Kelvin (W/m·K), AlON has a thermal conductivity of about 15-20 W/m·K, and AlN has a tailorable thermal conductivity of around 40-180 W/m·K. Accordingly, AlON may be selected if a lesser heat transfer rate of heat from the substrate to the substrate support assembly is deemed beneficial. Alternatively, sapphire or AN may be selected if a higher heat transfer rate is deemed beneficial.

At block 925, a determination is made as to whether any additional heating and/or cooling cycles are to be performed. If additional heating and/or cooling cycles are to be performed, the method returns to block 905. Otherwise the method ends. In some embodiments, the substrate may be heated and/or cooled as many as 20 times or more in a single process.

Method 900 is performed to alternately heat and cool a substrate during processing using substrate support assemblies described with reference to embodiments above. Traditional substrate support assemblies are capable of performing either heating of a substrate or cooling of a substrate, but not both heating and cooling of the substrate. The ability to both heat and cool a substrate as provided in embodiments herein enables numerous new processes to be implemented.

Electrostatic chucks and substrate support assemblies that can perform direct optical heating of substrates have been disclosed. The foregoing description discloses example embodiments of the invention. Modifications of the above-disclosed apparatus, systems, and methods which fall within the scope of the invention will be readily apparent to those of ordinary skill in the art. Accordingly, the present invention has been disclosed in connection with example embodiments, and it should be understood that other embodiments may fall within the scope of the invention, as defined by the following claims.

What is claimed is:

1. A substrate support assembly, comprising:
a ceramic plate having an optical transmittance of at least 60% at a predetermined wavelength, the ceramic plate comprising a top surface and a bottom surface, wherein the top surface is to support a substrate;
a base coupled to the bottom surface of the ceramic plate; and
a light carrying medium disposed in the base, the light carrying medium to direct light having the predetermined wavelength onto the bottom surface of the ceramic plate, wherein a majority of energy from the light is to pass through the ceramic plate and be absorbed by the substrate.

2. The substrate support assembly of claim 1, wherein the substrate comprises silicon and the ceramic plate comprises at least one of aluminum nitride, aluminum oxy-nitride, spinel, sapphire or Y₃Al₅O₁₂ (YAG).

3. The substrate support assembly of claim 1, wherein the predetermined wavelength is about 0.25-5.0 microns.

4. The substrate support assembly of claim 1, wherein the base bonded to the ceramic plate and the base is a cooling base.

5. The substrate support assembly of claim 1, wherein the ceramic plate is an electrostatic chuck and comprises an electrode layer, the electrode layer comprising a plurality of holes, wherein light emitted by the light carrying medium is to pass through at least one of the plurality of holes in the electrode layer.

6. The substrate support assembly of claim 1, wherein the ceramic plate is an electrostatic chuck and comprises an electrode layer, wherein the electrode layer comprises at least one of indium tin oxide or aluminum zinc oxide and has an optical transmittance of at least 80% at the predetermined wavelength and is electrically conductive.

7. The substrate support assembly of claim 1, wherein the light carrying medium comprises a plurality of optical fibers.

8. The substrate support assembly of claim 1, further comprising:
a gas channel in the ceramic plate, wherein the gas channel is to connect to a vacuum pump that is to evacuate a region between the substrate and the top surface of the ceramic plate.

9. The substrate support assembly of claim 1, wherein the substrate support assembly is to heat the substrate at a rate of 2-20° C. per second.

10. The substrate support assembly of claim 1, further comprising:
a light source to output the light at the predetermined wavelength.

11. The substrate support assembly of claim 12, wherein the light source is disposed within the base.

12. A substrate support assembly comprising:
a ceramic plate comprising a top surface and a bottom surface, wherein the top surface is to support a substrate that is to be heated to a first target temperature and cooled to a second target temperature;
a cooling base coupled to the bottom surface of the ceramic plate, wherein the cooling base is to be maintained at or below the second target temperature and is to cool the substrate to the second target temperature; and
a light carrying medium disposed in the cooling base, the light carrying medium to direct light from a light source onto at least one of the substrate or the bottom surface of the ceramic plate, wherein the light is to heat the substrate to the first target temperature that is above the second target temperature.

13. The substrate support assembly of claim 12, further comprising an electrode in the ceramic plate, wherein the electrode is a mesh, and wherein a radio frequency signal is to be applied to at least one of the electrode or the cooling base.

14. The substrate support assembly of claim 12, further comprising:
a plurality of rings bonded to the bottom surface of the ceramic plate, the plurality of rings comprising at least one of kovar or molybdenum;
at least one of a metal tube or a metal bellows coupled to a first ring of the plurality of rings; and
a metal backside cover coupled to a second ring.

15. The substrate support assembly of claim 12, wherein the light carrying medium is additionally disposed in the ceramic plate.

16. The substrate support assembly of claim 15, wherein the light has a wavelength of 0.25-5.0 microns.

17. The substrate support assembly of claim 15, wherein the light carrying medium comprises a plurality of light pipes, wherein the light source comprises a plurality of light sources, and wherein each of the plurality of light sources is coupled to at least one of the plurality of light pipes.

18. The substrate support assembly of claim 15, wherein the cooling base further comprises the light source disposed inside of the cooling base, the light source comprising a laser diode.

19. A method comprising:
performing, by a substrate support assembly, optical heating of a substrate to a first target temperature at a first rate of approximately 2-20° C. per second;
activating an electrode of the substrate support assembly to thermally couple the substrate to the substrate support assembly, wherein the substrate support assembly is maintained at a second temperature that is below the target temperature; and
cooling, by the substrate support assembly, the substrate to a second target temperature that is below the first target temperature at a second rate of approximately 2-20° C. per second.

20. The method of claim 19, further comprising:
deactivating the electrode of the substrate support assembly to thermally decouple the substrate from the substrate support assembly;
again performing the optical heating of the substrate to the first target temperature at the first rate;
again activating the electrode of the substrate support assembly to thermally couple the substrate to the substrate support assembly; and
again cooling the substrate to the second target temperature at the second rate.
